(19) United States
(12) Patent Application Publication
(10) Pub. No.: US 2008/0045023 A1
(43) Pub. Date: Feb. 21, 2008

(54) Method for manufacturing semiconductor device, and semiconductor device

(75) Inventor: Kei Kanemoto, Suwa-gun (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/811,478

(22) Filed: Jun. 11, 2007

(30) Foreign Application Priority Data
Jun. 30, 2006 (JP) 2006-181370

(51) Int. Cl. H01L 27/12; H01L 21/311

(52) U.S. Cl. 438/697; 257/347; 257/E27.112; 257/E21.249

(57) ABSTRACT

A method for manufacturing a semiconductor device includes: a) forming a first single-crystalline semiconductor layer having a higher etching selection ratio than a semiconductor substrate, in a manner covering an exposed part of a single-crystalline region on an active surface of the semiconductor substrate; b) forming a second single-crystalline semiconductor layer having smaller etching selection ratio than the first single-crystalline semiconductor layer, in a manner covering the first single-crystalline layer; c) removing and opening the second single-crystalline semiconductor layer and the first single-crystalline semiconductor layer within a region, the region being adjacent to an element region formed of a part of the second single-crystalline semiconductor layer and sandwiching the element region, so as to form a recess for a support, the recess exposing the semiconductor substrate; d) forming a support precursor layer over the active surface of the semiconductor substrate in a manner filling the recess for a support and covering the element region; e) removing a part, other than a part including the recess and the element region, of the support precursor layer by etching so as to form the support; f) forming an exposed face exposing at least a part of an end part of the first single-crystalline semiconductor layer and the second single-crystalline semiconductor layer by using the support as a mask; g) removing the first single-crystalline semiconductor layer by wet-etching; h) filling a gap, the gap being obtained by the wet-etching, with an oxide film by thermal oxidation; i) forming a planarized insulating layer, and planarizing the active surface of the semiconductor substrate by chemical mechanical polishing (CMP) method; j) etching the planarized insulating layer by the wet-etching using an etchant containing hydrofluoric acid so as to expose the second single-crystalline semiconductor layer; and k) forming a transistor on the second single-crystalline semiconductor layer. After the step c), a first side wall, the first side wall being resistant to the etchant, is formed on an end face, the end face being adjacent to the recess for a support, of the first single-crystalline semiconductor layer and the second single-crystalline semiconductor layer. After the step h), a second side wall, the second side wall being resistant to the etchant, is formed on the exposed face of the first single-crystalline semiconductor layer and the oxide film formed under the support.

### BACKGROUND

1. Technical Field

Several aspects of the present invention relate to a method for manufacturing a semiconductor device, and a semiconductor device. More particularly, the invention relates to a technique of forming a silicon on insulator (SOI) structure on a semiconductor device.

2. Related Art

For example, T. Sakai et al., Second International SiGe Technology and Device Meeting, Meeting Abstract, pp. 230-231, May 2004 discloses a method for manufacturing a semiconductor device having the SOI structure. The method forms an SOI layer on a part of a silicon substrate by separation by bonding Si islands (SBSI) method so as to form an SOI transistor on the SOI layer.

The method for forming the SOI structure by the SBSI method is now described. A silicon germanium (SiGe) layer and a silicon (Si) layer are grown epitaxially on a silicon substrate first and a recess for a support supporting the Si layer is formed next. Then an oxide film is formed and patterned to obtain shapes of an element forming region and the support. After that, the SiGe layer formed under the support is selectively etched, so that a cavity is formed under the Si layer in such manner that the Si layer is supported by the support. Then an oxide layer is grown from the silicon substrate and from the Si layer in the cavity by thermal oxidation so as to form a buried oxide (BOX) layer between the silicon substrate and the Si layer. After that, a top face of the silicon substrate is planarized, and etched with an etchant such as hydrofluoric acid to expose the Si layer, providing the SOI structure.

However, when forming the BOX layer in the cavity, as shown in FIG. 14, a first BOX layer 112 growing from a silicon substrate 111 and a second BOX layer 114 growing from a silicon layer 113 sometimes can not fill up the cavity, remaining a gap 115. Therefore, when exposing a surface of the Si layer 113 with the etchant such as hydrofluoric acid, in a case where the etching amount of the oxide layer 116 (the support) is large, that is a case where the oxide layer 116 is etched exceedingly from a position shown by the two-dot chain line showing a proper position to a position shown by the solid line that is in an arrow direction, due to variety of etching amount within the face of the wafer, the etchant enters between the first BOX layer 112 and the second BOX layer 114, peeling off the Si layer 113 as well as the second BOX layer 114.

### SUMMARY

An advantage of the present invention is provide a method for manufacturing a semiconductor device, and a semiconductor device in which a single-crystalline semiconductor layer in the SOI structure is prevented from peeling off.

A method for manufacturing a semiconductor device according to a first aspect of the invention includes: a) forming a first single-crystalline semiconductor layer having a higher etching selection ratio than a semiconductor substrate, in a manner covering an exposed part of a single-crystalline region on an active surface of the semiconductor substrate; b) forming a second single-crystalline semiconductor layer having smaller etching selection ratio than the first single-crystalline semiconductor layer, in a manner covering the first single-crystalline layer; c) removing and opening the second single-crystalline semiconductor layer and the first single-crystalline semiconductor layer within a region, the region being adjacent to an element region formed of a part of the second single-crystalline semiconductor layer and sandwiching the element region, so as to form a recess for a support, the recess exposing the semiconductor substrate; d) forming a support precursor layer over the active surface of the semiconductor substrate in a manner filling the recess for a support and covering the element region; e) removing a part, other than a part including the recess and the element region, of the support precursor layer by etching so as to form a support; f) forming an exposed face exposing at least a part of an end part of the first single-crystalline semiconductor layer and the second single-crystalline semiconductor layer by using the support as a mask; g) removing the first single-crystalline semiconductor layer by wet-etching; h) filling a gap, the gap being obtained by the wet-etching, with an oxide film by thermal oxidation; i) forming a planarized insulating layer, and planarizing the active surface of the semiconductor substrate by chemical mechanical polishing (CMP) method; j) etching the planarized insulating layer by the wet-etching using an etchant containing hydrofluoric acid so as to expose the second single-crystalline semiconductor layer; and k) forming a transistor on the second single-crystalline semiconductor layer. After the step c), a first side wall, the first side wall being resistant to the etchant, is formed on an end face, the end face being adjacent to the recess for a support, of the first single-crystalline semiconductor layer and the second single-crystalline semiconductor layer. After the step h), a second side wall, the second side wall being resistant to the etchant, is formed on the exposed face of the first single-crystalline semiconductor layer and the oxide film formed under the support.

According to the method, the whole periphery composed of end faces of the oxide film filled in place of the first single-crystalline semiconductor layer and the second single-crystalline semiconductor layer is covered by the first and second side walls which are resistant to the etchant. Therefore, even if the support and the planarized insulating layer formed around the second single-crystalline semiconductor layer are etched excessively in etching for exposing the top face of the second single-crystalline semiconductor layer, the first and second side walls can prevent the second single-crystalline semiconductor layer and the oxide layer from exposing. Thus, the second single-crystalline semiconductor layer can prevent its peel-off caused by the etchant.

A method for manufacturing a semiconductor device according to a second aspect of the invention includes: a) forming a first single-crystalline semiconductor layer including mixed crystal of silicon and germanium, in a manner covering an exposed part of a single-crystalline region on an active surface of a silicon substrate; b) forming a second single-crystalline semiconductor layer made of silicon having lower germanium ratio than the first single-crystalline semiconductor layer or single crystal containing only silicon, in a manner covering the first single-crystalline semiconductor layer; c) removing and opening the second single-crystalline semiconductor layer and the first single-crystalline semiconductor layer within a region, the region being adjacent to an element region formed of a part of the second single-crystalline semiconductor layer and sandwiching the element region, so as to form a recess for a support, the recess exposing the silicon substrate; d) forming a silicon oxide layer over the active surface of the silicon substrate in a manner filling the recess for a support and covering the element region; e) removing a part, other than a part including the recess and the element region, of the silicon oxide layer by etching so as to form a support; f) forming an exposed face exposing at least a part of an end part of the first single-crystalline semiconductor layer and the second single-crystalline semiconductor layer by using the support as a mask; g) removing the first single-crystalline semiconductor layer by wet-etching using a hydrofluoric nitric acid etchant; h) filling a gap, the gap being obtained by the wet-etching, with an oxide film by thermal oxidation; i) forming a planarized silicon oxide layer, and planarizing the active surface of the silicon substrate by chemical mechanical polishing method; j) etching the planarized silicon oxide layer by wet-etching using an etchant containing hydrofluoric acid so as to expose the second single-crystalline semiconductor layer; and k) forming a transistor on the second single-crystalline semiconductor layer. After the step c), a first side wall, the first side wall being resistant to the etchant containing hydrofluoric acid, is formed on an end face, the end face being adjacent to the recess for a support, of the first single-crystalline semiconductor layer and the second single-crystalline semiconductor layer. After the step h), a second side wall, the second side wall being resistant to the etchant containing the hydrofluoric acid, is formed on the exposed face of the first single-crystalline semiconductor layer and the oxide film formed under the support.

According to the method, the whole periphery composed of end faces of the oxide film filled in place of the first single-crystalline semiconductor layer and the second single-crystalline semiconductor layer is covered by the first and second side walls which are resistant to the etchant containing hydrofluoric acid. Therefore, even if the support and the planarized silicon oxide layer formed around the second single-crystalline semiconductor layer are etched excessively in etching for exposing the top face of the second single-crystalline semiconductor layer, the first and second side walls can prevent the second single-crystalline semiconductor layer and the oxide layer from exposing. Thus, the second single-crystalline semiconductor layer can prevent its peel-off caused by the etchant.

According to the method for manufacturing a semiconductor device of above aspects, the first side wall and the second side wall may be silicon nitride (SiN) film.

According to the method, since the first side wall and the second side wall are composed of silicon nitride film. Therefore, even if the support and the planarized silicon oxide layer are etched excessively in etching for exposing the second single-crystalline semiconductor layer with hydrofluoric acid, the first side wall and the second side wall composed of silicon nitride film can be left. Thus, the end face (exposed face) of the second single-crystalline semiconductor layer and the oxide film can be kept covered by the silicon nitride film, preventing the peel-off of the second single-crystalline semiconductor layer caused by the etchant.

A semiconductor device according to a third aspect of the invention includes: a silicon on insulator (SOI) structure, having: an oxide film formed within an element region on a single-crystalline region of a semiconductor substrate; a second single-crystalline semiconductor layer formed on the oxide film; a side wall, the side wall being formed on an end face of the second single-crystalline semiconductor layer and the oxide film and being resistant to an etchant containing hydrofluoric acid; and a silicon oxide layer insulating the second single-crystalline semiconductor layer from other part formed around the side wall.

According to the structure, the side wall is formed on the end face of the second single-crystalline semiconductor layer and the oxide film. Therefore, the etchant can be prevented from contacting the end face of the second single-crystalline semiconductor layer and the oxide film in etching for exposing the second single-crystalline semiconductor layer. Thus, the semiconductor device in which peel-off of the second single-crystalline semiconductor layer is prevented can be provided. Further, the semiconductor device in which the peel-off of the second single-crystalline semiconductor layer is prevented can be distinguished from a semiconductor device in which the peel-off of the second single-crystal semiconductor layer is not prevented.

### BRIEF DESCRIPTION OF THE DRAWINGS

The invention will be described with reference to the accompanying drawings, wherein like numbers reference like elements.

FIGS. 1A and 1B are schematic views showing a method for manufacturing a semiconductor device according to an embodiment of the invention. FIG. 1A is a schematic plan view, and FIG. 1B is a schematic sectional view.

FIGS. 2A and 2B are schematic views showing the method for manufacturing a semiconductor device. FIG. 2A is a schematic plan view, and FIG. 2B is a schematic sectional view.

FIGS. 3A and 3B are schematic views showing the method for manufacturing a semiconductor device. FIG. 3A is a schematic plan view, and FIG. 3B is a schematic sectional view.

FIGS. 4A and 4B are schematic views showing the method for manufacturing a semiconductor device. FIG. 4A is a schematic plan view, and FIG. 4B is a schematic sectional view.

FIGS. 5A and 5B are schematic views showing the method for manufacturing a semiconductor device. FIG. 5A is a schematic plan view, and FIG. 5B is a schematic sectional view.

FIGS. 6A and 6B are schematic views showing the method for manufacturing a semiconductor device. FIG. 6A is a schematic plan view, and FIG. 6B is a schematic sectional view.

FIGS. 7A and 7B are schematic views showing the method for manufacturing a semiconductor device. FIG. 7A is a schematic plan view, and FIG. 7B is a schematic sectional view.

FIGS. 8A and 8B are schematic views showing the method for manufacturing a semiconductor device. FIG. 8A is a schematic plan view, and FIG. 8B is a schematic sectional view.

FIGS. 9A and 9B are schematic views showing the method for manufacturing a semiconductor device. FIG. 9A is a schematic plan view, and FIG. 9B is a schematic sectional view.

FIGS. 10A and 10B are schematic views showing the method for manufacturing a semiconductor device. FIG. 10A is a schematic plan view, and FIG. 10B is a schematic sectional view.

FIGS. 11A and 11B are schematic views showing the method for manufacturing a semiconductor device. FIG. 11A is a schematic plan view, and FIG. 11B is a schematic sectional view.

FIGS. 12A and 12B are schematic views showing the method for manufacturing a semiconductor device. FIG. 12A is a schematic plan view, and FIG. 12B is a schematic sectional view.

FIG. 13 is an enlarged sectional view showing an enlarged part of FIG. 11B.

FIG. 14 is a schematic sectional view showing a conventional method for manufacturing a semiconductor device.

### DESCRIPTION OF EXEMPLARY EMBODIMENT

Embodiments of the present invention will now be described with reference to the accompanying drawings.

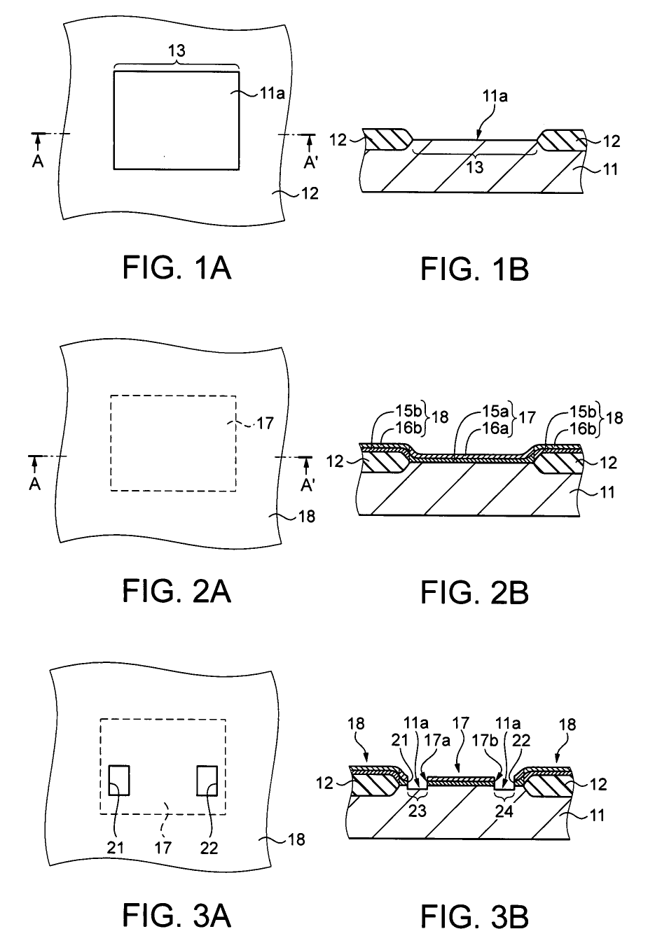

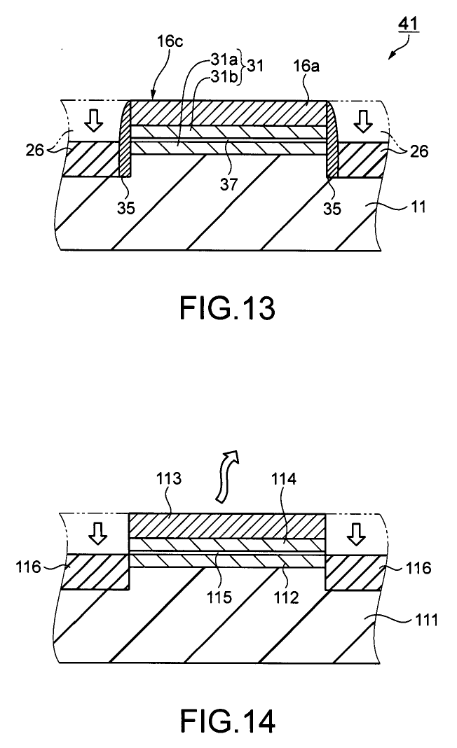

FIGS. 1A to 12B are schematic views showing a method for manufacturing a semiconductor device in a process order. In FIGS. 1A to 12B, each figure suffixed with the letter A is a schematic plan view, while each figure suffixed with the letter B is a schematic sectional view taken along the line A-A′ in respective figures suffixed with the letter A. FIG. 13 is an enlarged sectional view showing an enlarged part of FIG. 11B. The method for manufacturing a semiconductor device will now be described with reference to FIGS. 1A to 13.

In a process shown in FIGS. 1A and 1B, an element isolation layer 12 and an SOI forming region 13 are formed on an active surface of a silicon substrate 11 as a semiconductor substrate constituting a semiconductor device. The element isolation layer 12 is, for example, a local oxidation of silicon (LOCOS) oxide film, and formed so as to electrically insulate the SOI forming region 13 from a bulk forming region (not shown). Hereinafter, the description of the bulk forming region is omitted. First, a silicon oxide (SiO₂) film which is not shown is formed over the silicon substrate 11. Then a silicon nitride (SiN) film which is not shown is formed on the SOI forming region 13 of the silicon substrate 11 by photolithography and etching. After that, the silicon substrate 11 other than the SOI forming region 13 is oxidized by using the SiN film as a mask so as to form the element isolation layer 12.

Next, the surface 11a of the silicon substrate 11 is exposed in the SOI forming region 13. A resist film (not shown) having an opening corresponding to the SOI forming region 13 is first formed over the silicon substrate 11 by photolithography. The SiO₂ film on the SOI forming region 13 is next removed by etching using the resist film as a mask. Thus, the surface 11a of the silicon substrate 11 is exposed only within the SOI forming region 13 which is a single-crystalline region.

In a process shown in FIGS. 2A and 2B, a silicon germanium (SiGe) layer 15 and a silicon (Si) layer 16 are formed over the silicon substrate 11 with an epitaxial growth technique. The SiGe layer 15 is made, for example, of mixed crystal of silicon and germanium. Further, adding carbon (C), for example, to the mixed crystal of silicon and germanium provides more film thickness to be able to reduce a parasitic capacitance. The Si layer 16 is made, for example, of silicon having lower germanium ratio than the SiGe layer 15 or silicon added no germanium.

To a region exposing the surface 11a of the silicon substrate 11 (refer to FIG. 1B) is provided a single crystalline epitaxial film 17 including a first SiGe layer 15a as a first single-crystalline semiconductor layer and a first Si layer 16a as a second single-crystalline semiconductor layer which are grown as single crystal. On the other hand, to the element isolation layer 12 is provided a polycrystalline epitaxial film 18 including a second SiGe layer 15b and a second Si layer 16b which are grown as polycrystal. In order to improve the crystallinity of the SiGe layer 15, a silicon buffer layer (not shown) may be formed over the silicon substrate 11 by epitaxial growth before forming the SiGe layer 15. The thickness of the silicon buffer layer is, for example, 20 nm. The thickness of the SiGe layer 15 is, for example, 30 nm. The thickness of the Si layer 16 is, for example, 100 nm.

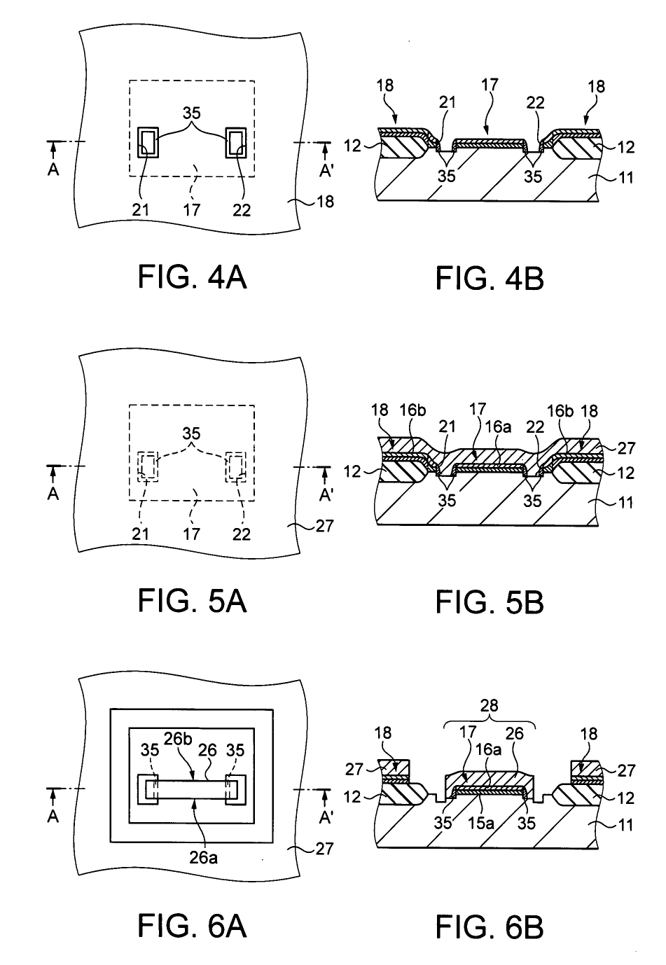

Next, a silicon oxide (SiO₂) film which is not shown is formed over the Si layer 16 by, for example, thermal oxidation. The SiO₂ film is formed at such temperature that germanium (Ge) contained in the SiGe layer 15 is not diffused, that is less than or equal to 800 degrees Celsius, for example. Alternatively, the SiO₂ film may be formed by chemical vapor deposition (CVD) instead of thermal oxidation. The thickness of the SiO₂ film is, for example, 50 nm. Thus, the SiO₂ film is formed over the single crystalline epitaxial film 17 and the polycrystalline epitaxial film 18. This SiO₂ film is used, for example, in the following process of forming first side walls 35 (refer to FIGS. 4A and 4B) so as to provide a selection ratio to the first side walls 35 (silicon nitride layer). Hereinafter, the description of the SiO₂ film is omitted.

In a process shown in FIGS. 3A and 3B, a first recess 21 and a second recess 22 for a support are formed on the single-crystalline epitaxial film 17. First, a resist pattern (not shown) is formed by photolithography. The resist pattern has openings corresponding to a first recess forming region 23 on which the first recess 21 is to be formed and a second recess forming region 24 on which the second recess 22 is to be formed. Next, parts, corresponding to the first recess forming region 23 and the second recess forming region 24, of each of the first Si layer 16a, the first SiGe layer 15a (refer to FIGS. 2A and 2B), and the silicon substrate 11 are removed by dry-etching in sequence by using the resist pattern as a mask. Thus, the first recess 21 and the second recess 22 for a support are formed in the SOI forming region 13 (refer to FIGS. 1A and 1B).

Further, forming the first recess 21 and the second recess 22 exposes a first side face 17a and a second side face 17b of the single-crystalline epitaxial film 17, and the surface 11a of the silicon substrate 11. A region between the first recess 21 and the second recess 22 is the element forming region.

In a process shown in FIGS. 4A and 4B, first side walls 35 are formed on side walls (end faces of the single-crystalline epitaxial film 17) of the recesses 21 and 22 for a support. First, a silicon nitride (SiN) film, for example, which is etching-resistant to hydrofluoric acid and is not shown is formed over the silicon substrate 11 by CVD. The thickness of the SiN film is, for example, 50 nm. The SiN film is formed at such temperature that germanium contained in the SiGe layer 15 is not diffused. Next, the SiN film is etched back so as to form the first side walls 35 composed of the SiN film on the side walls of the recesses 21 and 22. This etching treatment is performed in a higher etching rate than that of the SiO₂ film. Thus, the side walls of the recesses 21 and 22, that is end faces of the first SiGe layer 15a and the first Si layer 16a exposed due to the recesses 21 and 22 can be covered by the first side walls 35.

In a process shown in FIGS. 5A and 5B, a support precursor layer 27 for forming a support 26 (refer to FIGS. 6A and 6B) is formed over the silicon substrate 11. The support precursor layer 27 is, for example, a silicon oxide (SiO₂) film. More particularly, the support precursor layer 27 such as an SiO₂ film is formed over the silicon substrate 11 in a manner infilling the first recess 21 and the second recess 22 which are provided with the side walls 35, and covering the Si layers 16a and 16b by, for example, chemical vapor deposition (CVD). The support precursor layer 27 is formed at such temperature that germanium contained in the SiGe layer 15 is not diffused. The thickness of the support precursor layer 27 is, for example, 400 nm.

In a process shown in FIGS. 6A and 6B, the support 26 for supporting the first Si layer 16a is completed. First, a part, other than a part corresponding to a support forming region 28 on which the support 26 is to be formed, of the support precursor layer 27 is removed. The part is removed by dry-etching using a resist pattern (not shown) having an opening corresponding to a part excluding a planar region of the support 26, as a mask. Thus, the support 26 is completed. Further, a part, other than a part corresponding to the support forming region 28, of the single-crystalline epitaxial film 17 and the polycrystalline epitaxial film 18 is removed by dry-etching using the support 26 as a mask. Thus, the process exposes a first side face 26a and a second side face 26b of the support 26, and end faces (front and rear faces in FIG. 6B) of the single-crystalline epitaxial film 17 under the first side face 26a and the second side face 26b of the support 26. Here, the end faces of the single-crystalline epitxial film 17 are called exposed faces.

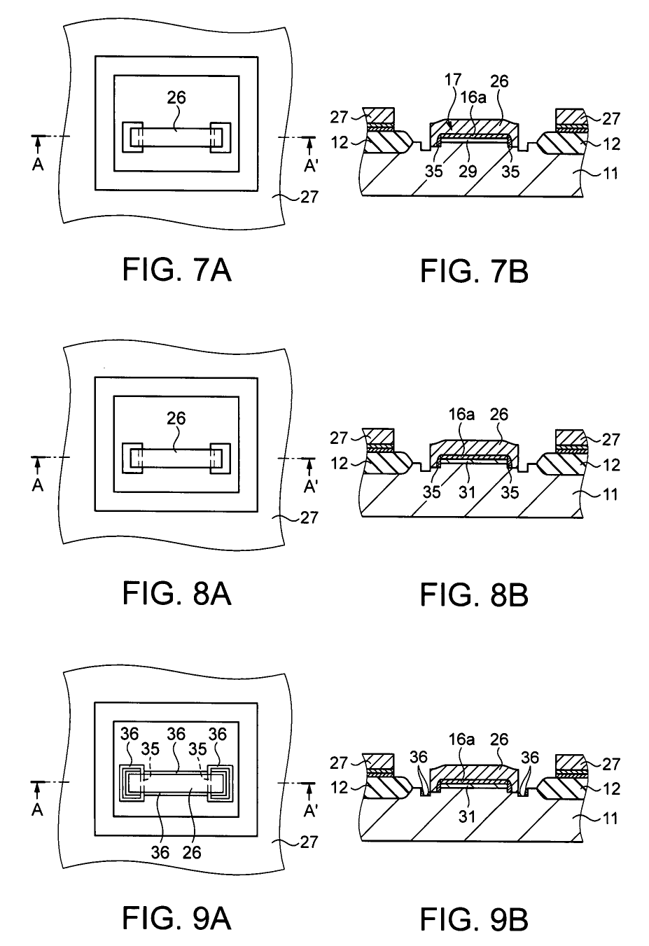

In a process shown in FIGS. 7A and 7B, the first SiGe layer 15a (refer to FIG. 6B) formed under the support 26 is removed selectively by etching with hydrofluoric-nitric acid. First, the single-crystalline epitaxial film 17 formed under the support 26 is contacted with an etchant such as hydrofluoric-nitric acid. Here, the etching starts from the exposed faces of the single-crystalline epitaxial film 17. Since the first Si layer 16a is etched more slowly than the first SiGe layer 15a, the first SiGe layer 15a can be selectively etched to be removed in a manner leaving the first Si layer 16a. Further, the first side walls 35 and the support 26 which are formed in advance are capable of supporting the first Si layer 16a. Consequently, a cavity 29 as a vacancy is formed between the silicon substrate 11 and the first Si layer 16a.

In a process shown in FIGS. 8A and 8B, a buried insulating layer (BOX layer: buried oxide layer) 31 is formed in the cavity 29 (refer to FIG. 7B). The buried insulating layer 31 is, for example, a silicon oxide film, and formed by thermal oxidization by which silicon contained in the silicon substrate 11 and the first Si layer 16a reacts with oxygen. An oxide film formed on the silicon substrate 11 is a first buried insulating layer 31a (refer to FIG. 13). On the other hand, an oxide film formed on the first Si layer 16a is a second buried insulating layer 31b (refer to FIG. 13). The growth rate of the first and second buried insulating layers 31a and 31b decides whether the cavity 29 can be filled up with the oxide film, or can not be filled to leave a gap 37 (refer to FIG. 13).

In a process shown in FIGS. 9A and 9B, second side walls 36 (especially refer to FIG. 9A) are formed on exposed side walls (end faces) of the first Si layer 16a and the buried insulating layer 31. First, a silicon nitride (SiN) film, for example, is formed over the silicon substrate 11 by CVD. The thickness of the SiN film is, for example, 50 nm. Next, the SiN film is etched back so as to form the second side walls 36 composed of the SiN film on the side walls of the buried insulating layer 31 and the first Si layer 16a. The SiN film is etched in sufficiently higher etching rate than that of the SiO₂ film. The second side walls 36 may be formed by etching back the SiN film up to a border of the support 26 and the first Si layer 16a (refer to FIG. 9B) while extending the etching time, for example. Thus, the whole periphery composed of the end faces (side faces) of the first Si layer 16a and the buried insulating layer 31 is covered by the first side walls 35 and the second side walls 36.

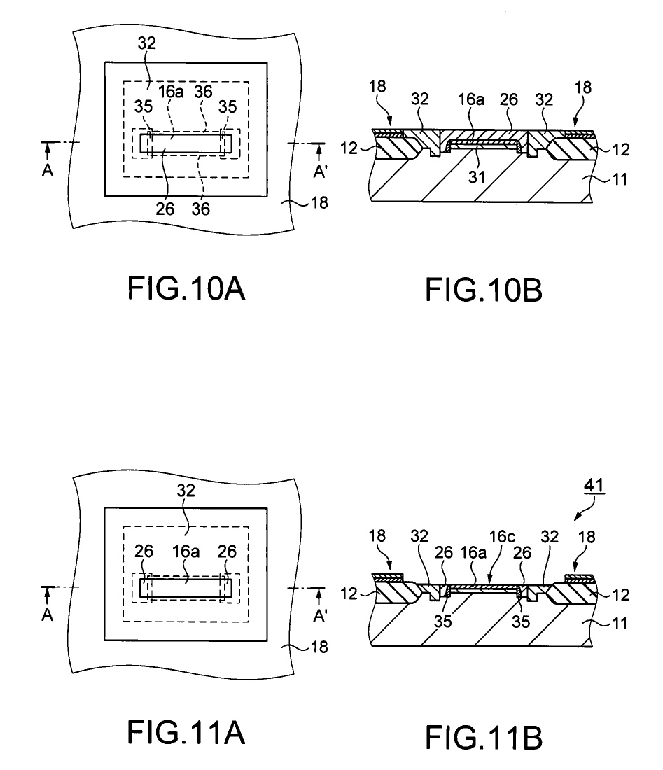

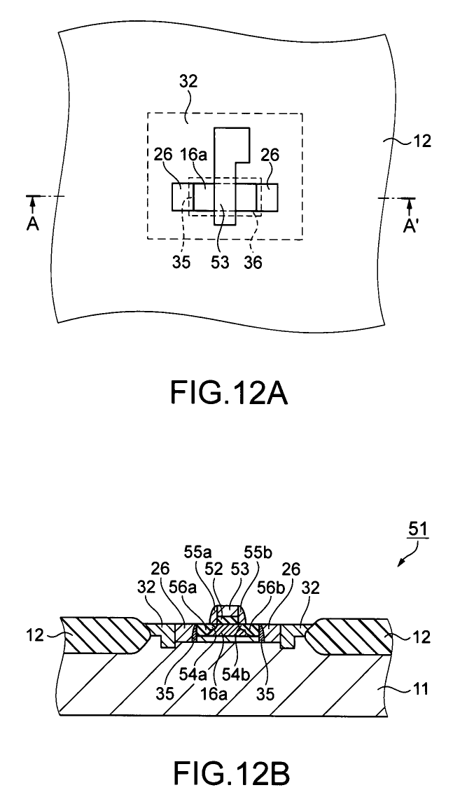

In a process shown in FIGS. 10A and 10B, the whole surface on the silicon substrate 11 is planarized. Here, in FIGS. 10A and 10B (same as in FIGS. 11A to 12B), the first side walls 35 and the second side walls 36 are drawn only at the periphery of the first Si layer 16a and the buried insulating layer 31 which are formed under the support 26. First, an insulating film 32 as a planarized silicon oxide film is formed over the silicon substrate 11 so as to electrically insulate the SOI structure. The insulating film 32 is formed by, for example, CVD. The thickness of the insulating film 32 is, for example, 1 μm. Next, the whole surface of the silicon substrate 11 is planarized by chemical mechanical polishing (CMP) while using the polycrystalline epitaxial film 18 on the element isolation layer 12 as a stopper layer. Thus, a part of the insulating film 32 and the support 26 is removed.

In a process shown in FIGS. 11A and 11B, an unnecessary part of the support 26 and the insulating film 31 is removed down to the top face 16c of the first Si layer 16a so as to complete a base 41. An etchant is, for example, hydrofluoric acid. An etchant containing hydrofluoric acid may be used. Using the etchant removes the parts of the support 26 and the insulating film 32 to expose the top face 16c of the first Si layer 16a. Consequently, the first Si layer 16a is isolated by the insulating film 32 and the buried insulating layer 31 on the silicon substrate 11, completing the base 41.

Here, referring to FIG. 13, a case where the etching amount of the support 26 and the insulating film 32 (refer to FIGS. 11A and 11B) on the base 41 is large is now described. The buried insulating layer 31 is composed of the first buried insulating layer 31a and the second insulating layer 31b. The first and second insulating layers 31a and 31b sometimes fill up between the silicon substrate 11 and the first Si layer 16a insufficiently (bonded each other insufficiently), leaving the gap 37. The support 26 (the insulating film 32) is etched so as to expose the top face 16c of the first Si layer 16a. Even when the etching amount of the support 26 is large (for example, the support 26 is etched from a position shown by the two-dot chain line to a position shown by the solid line, that is in the arrow direction), the etchant such as hydrofluoric acid can be prevented from entering the gap 37 because the whole periphery composed of the end faces of the first Si layer 16a and the buried insulating layers 31a and 31b is covered by the first side walls 35 and the second side walls 36 (refer to FIG. 10a).

In addition, between the side walls 35, 36 and the first Si layer 16a, a thermal oxide film which is not shown is provided when the buried insulating layer 31 is formed. The etching rate of the thermal oxide film is smaller than that of the support 26 and the insulating film 32 which are formed by CVD and the like. Therefore, even if the thermal oxide film is etched in etching by hydrofluoric acid, it is not etched very much. Thus, the etchant can be prevented from entering the gap 37, even when the support 26 (the insulating film 32) is etched excessively in etching.

In a process shown in FIGS. 12A and 12B, a semiconductor device 51 is completed. First, the surface of the first Si layer 16a is thermally oxidized to form a gate insulating film 52. Then, a polycrystalline silicon layer is formed on the gate insulating film 52 by CVD, for example. After that, the polycrystalline silicon layer is patterned by photolithography and etching so as to form a gate electrode 53 on the gate insulating film 52.

Next, impurity ions such as arsenic (As), phosphorus (P), boron (B), and the like are implanted into the first Si layer 16a by using the gate electrode 53 as a mask, forming LDD layers 54a and 54b composed of low concentration impurity introduction layers at lateral areas of the gate electrode 53 on the first Si layer 16a. Then, an insulating layer is formed on the first Si layer 16a provided with the LDD layers 54a and 54b, by CVD, for example, and the insulating layer is etched back by dry-etching such as reactive ion etching (RIE), forming side walls 55a and 55b on side walls of the gate electrode 53.

Further, impurity ions such as As, P, B are implanted into the first Si layer 16a by using the gate electrode 53 and the side walls 55a and 55b as a mask. Thus, source-drain electrode layers 56a and 56b composed of high concentration impurity introduction layers are formed on lateral areas of the side walls 55a and 55b on the first Si layer 16a. Thus, a transistor is completed. Further, a bulk element is formed on the bulk forming region (not shown), completing the semiconductor device 51 in which the SOI element and the bulk element are mounted together on the silicon substrate 11.

According to the method for manufacturing the semiconductor device 51 described above, the following advantageous effects are obtained.

According to the method for manufacturing the semiconductor device 51 of the embodiments, the whole periphery composed of the exposed faces (end faces) of the first Si layer 16a and the buried insulating layer 31 is covered by the first and second side walls 35 and 36 which are resistant to hydrofluoric acid. Therefore, even if the support 26 and the insulating film 32 formed around the periphery of the first Si layer 16a are etched excessively in etching by hydrofluoric acid for exposing the top face 16c of the first Si layer 16a, the first and second side walls 35 and 36 composed of silicon nitride (SiN) films can be left. Thus, the end faces of the first Si layer 16a and the buried insulating layer 31 can be prevented from being exposed. Even if the cavity 29 is not sufficiently filled up with the buried insulating layer 31 to form the gap 37 (the buried insulating layers 31a and 31b are insufficiently bonded each other), the etchant such as hydrofluoric acid can be prevented from entering the gap 37, preventing the first Si layer 16a peeling off at the gap 37 as a boundary.

Note that the embodiments are not limited to the above, but can be applied as follows.

First Modification: The second side walls 36 formed after the cavity 29 is filled with the buried insulating layer 31 are composed of the silicon nitride film in the above description. Alternatively, the second side walls 36 may be made of materials which are resistant to hydrofluoric acid, and selection ratio with silicon is high, such as polysilicon. Using polysilicon can reduce stress given to the first Si layer 16a.

Second Modification: While the cavity 29 is filled with the buried insulating layer 31 in the above description, the cavity 29 may adopt a silicon on nothing (SON) structure in which the buried insulating layer is formed thinly, for example, to leave a gap in the cavity 29 from the beginning. Such structure can reduce dielectric constant, compared to SOI. Further, since forming the thermal oxide film between the first silicon layer 16a and the side walls 35, 36 can be restrained, hydrofluoric acid can be prevented from entering the cavity 29, as the buried insulating layer 31.

Third Modification: The first and second side walls 35 and 36 are formed around the whole periphery composed of the end faces of the first Si layer 16a and the buried insulating layer 31 in the above description. Alternatively, only the first side walls 35 on the sides where the support 26 sandwiches the first Si layer 16a may be formed without forming the second side walls 36. The first side walls 35 support the first Si layer 16a, so that the first Si layer 16a can be prevented from peeling off even if hydrofluoric acid enters the gap 37 (refer to FIG. 13).

The entire disclosure of Japanese Patent Application No: 2006-181370, filed Jun. 30, 2006 is expressly incorporated by reference herein.

What is claimed is:

1. A method for manufacturing a semiconductor device, comprising:
a) forming a first single-crystalline semiconductor layer having a higher etching selection ratio than a semiconductor substrate, in a manner covering an exposed part of a single-crystalline region on an active surface of the semiconductor substrate;
b) forming a second single-crystalline semiconductor layer having smaller etching selection ratio than the first single-crystalline semiconductor layer, in a manner covering the first single-crystalline layer;
c) removing and opening the second single-crystalline semiconductor layer and the first single-crystalline semiconductor layer within a region, the region being adjacent to an element region formed of a part of the second single-crystalline semiconductor layer and sandwiching the element region, so as to form a recess for a support, the recess exposing the semiconductor substrate;
d) forming a support precursor layer over the active surface of the semiconductor substrate in a manner filling the recess for a support and covering the element region;
e) removing a part, other than a part including the recess and the element region, of the support precursor layer by etching so as to form the support;
f) forming an exposed face exposing at least a part of an end part of the first single-crystalline semiconductor layer and the second single-crystalline semiconductor layer by using the support as a mask;
g) removing the first single-crystalline semiconductor layer by wet-etching;
h) filling a gap, the gap being obtained by the wet-etching, with an oxide film by thermal oxidation;
i) forming a planarized insulating layer, and planarizing the active surface of the semiconductor substrate by chemical mechanical polishing (CMP) method;
j) etching the planarized insulating layer by the wet-etching using an etchant containing hydrofluoric acid so as to expose the second single-crystalline semiconductor layer; and
k) forming a transistor on the second single-crystalline semiconductor layer, wherein
after the step c), a first side wall, the first side wall being resistant to the etchant, is formed on an end face, the end face being adjacent to the recess for a support, of the first single-crystalline semiconductor layer and the second single-crystalline semiconductor layer, and
after the step h), a second side wall, the second side wall being resistant to the etchant, is formed on the exposed face of the first single-crystalline semiconductor layer and the oxide film formed under the support.

2. A method for manufacturing a semiconductor device, comprising:
a) forming a first single-crystalline semiconductor layer including mixed crystal of silicon and germanium in a manner covering an exposed part of a single-crystalline region on an active surface of a silicon substrate;
b) forming a second single-crystalline semiconductor layer made of silicon having lower germanium ratio than the first single-crystalline semiconductor layer or single crystal containing only silicon, in a manner covering the first single-crystalline semiconductor layer;
c) removing and opening the second single-crystalline semiconductor layer and the first single-crystalline semiconductor layer within a region, the region being adjacent to an element region formed of a part of the second single-crystalline semiconductor layer and sandwiching the element region, so as to form a recess for a support, the recess exposing the silicon substrate;
d) forming a silicon oxide layer over the active surface of the silicon substrate in a manner filling the recess for a support and covering the element region;
e) removing a part, other than a part including the recess and the element region, of the silicon oxide layer by etching so as to form a support;
f) forming an exposed face exposing at least a part of an end part of the first single-crystalline semiconductor layer and the second single-crystalline semiconductor layer by using the support as a mask;
g) removing the first single-crystalline semiconductor layer by wet-etching using a hydrofluoric nitric acid etchant;
h) filling a gap, the gap being obtained by the wet-etching, with an oxide film by thermal oxidation;
i) forming a planarized silicon oxide layer, and planarizing the active surface of the silicon substrate by chemical mechanical polishing (CMP) method;
j) etching the planarized silicon oxide layer by wet-etching using an etchant containing hydrofluoric acid so as to expose the second single-crystalline semiconductor layer; and
k) forming a transistor on the second single-crystalline semiconductor layer, wherein
after the step c), a first side wall, the first side wall being resistant to the etchant containing hydrofluoric acid, is formed on an end face, the end face being adjacent to the recess for a support, of the first single-crystalline semiconductor layer and the second single-crystalline semiconductor layer, and
after the step h), a second side wall, the second side wall being resistant to the etchant containing the hydrofluoric acid, is formed on the exposed face of the first single-crystalline semiconductor layer and the oxide film formed under the support.

3. The method for manufacturing a semiconductor device according to claim 1, wherein the first side wall and the second side wall are silicon nitride (SiN) film.

4. A semiconductor device, comprising:
a silicon on insulator (SOI) structure, including:
an oxide film formed within an element region on a single-crystalline region of a semiconductor substrate,
a second single-crystalline semiconductor layer formed on the oxide film,
a side wall, the side wall being formed on an end face of the second single-crystalline semiconductor layer and the oxide film and being resistant to an etchant containing hydrofluoric acid, and
a silicon oxide layer insulating the second single-crystalline semiconductor layer from other part formed around the side wall.
